(19) United States
(12) Patent Application Publication
(10) Pub. No.: US 2010/0277223 A1
(43) Pub. Date: Nov. 4, 2010

(54) Voltage/current reference using thermal electric feedback

(76) Inventor: Fred Mirow, Lower Merion, PA (US)

Correspondence Address: Fred Mirow, 118 CORNELL RD, BALA CYNWYD, PA, 19004, US

(21) Appl. No.: 12/661,817

(22) Filed: Mar. 24, 2010

Related U.S. Application Data
(60) Provisional application No. 61/215,150, filed on May 4, 2009.

(51) Int. Cl. H03K 3/42

(52) U.S. Cl. 327/513

(57) ABSTRACT

Voltage and current reference sources capable of providing an output signal level which is insensitive to temperature variations, radiation, and to variations in the input voltage supplied to the reference circuit. The reference output level is used to vary the temperature of at least one resistor that is in a resistor bridge network. By applying resistor temperature variation as negative feedback the voltage and current reference sources output voltage level is maintained at a relatively constant level.

### CROSS-REFERENCE TO RELATED APPLICATIONS

The benefits of filing this invention as Provisional application for patent “Voltage/Current Reference Using Thermal Electric Feedback”, U.S. PTO No. 61/215,150 filed May 4, 2009 by Fred Mirow are claimed.

### BACKGROUND OF THE INVENTION

This invention relates generally to circuits and, more particularly, to voltage and current reference sources capable of providing an output signal level which is insensitive to temperature variations, radiation, and to variations in the input voltage supplied to the reference circuit.

Stable voltage and current reference are required for the operation of circuits such as A/D converters, and measurement devices to name only a few.

Most electronic reference requires the use of a zener or bandgap in their circuit. These references depend on semiconductor properties that are useful over limited temperature range, and radiation levels.

Accordingly, one of the objects of the invention is to provide electronic references, which are insensitive to temperature variations, radiation, and to variations in the input voltage supplied to the reference circuit.

Another objective is to provide voltage and current reference systems that have high temperature, radiation, and voltage stability due to its reliance on resistor ratios to set circuit threshold operating values.

It is an additional object of the invention to provide electronic reference circuits that are less susceptible to process variances by relying on impedance ratios thereby providing a more consistently manufacturable circuit.

### BRIEF SUMMARY OF THE INVENTION

According to this invention, the reference output level is used to vary the temperature of one or more resistors that are in a resistor bridge network. Each leg of the network comprising two temperature sensitive resistors of matching temperature coefficients so that the effects of ambient temperature are concealed out. Depending on the actual circuit used the temperature coefficients of the resistors in one leg do not need to match the temperature coefficients of the other leg. One leg of the network may actual comprise two resistors not sensitive to temperature. The bridge network output voltage level is fed to a differential input amplifier. The amplifier output voltage is applied to a relatively constant value resistor load that is thermally coupled back to at least one of the bridge network resistor, or in some cases directly to the bridge network resistor. As the voltage level across the resistor load increases it's temperature increases causing the resistance of the thermally coupled bridge network resistor to vary which causes the bridge network output voltage level to vary, since temperature of the other bridge network resistors has remained relatively constant. By applying resistor load temperature variation as negative feedback the amplifier output voltage level is driven to a relatively constant level that maintains the bridge network output voltage level near zero. In the case of the current reference the resistor load would be placed in series with the external load instead of in parallel.

The resistor load should be thermally coupled as tightly as possible to the intended resistor and should be thermally isolated to the greatest extent possible from all other bridge network resistors. It is preferable that all the bridge network resistors be subjected to the same ambient temperature. Also, the more linear the temperature coefficient of the temperature sensitive resistors are the more accurate the reference can be made over ambient temperature variations. Another method of improving the accuracy over wide ambient temperature variations is to place the bridge network resistors in a constant temperature oven. Common resistance materials for temperature sensitive resistors are Platinum, Nickel, Copper, Balco, and Tungsten. In addition, if being built as an integrated circuit, polysilicon or other doped silicon can also be used.

In some cases, the amplifier output voltage is applied directly to a bridge network resistor instead of a separate resistor load. The bridge network is powered by an AC voltage while the amplifier output voltage is converted to substantially a DC voltage.

As the DC voltage level across the bridge network resistor increases it's temperature increases causing it's resistance to vary, which causes the bridge network AC output voltage level to vary, since the temperature of the other bridge network resistors has remained relatively constant. By applying temperature variation of a bridge network resistor as negative feedback, the amplifier output voltage level is driven to a relatively constant level that maintains the bridge network AC output voltage level near zero.

In another case, the amplifier output voltage is converted to an AC voltage used to increase resistor temperature in the bridge network.

### BRIEF DESCRIPTION OF THE DRAWINGS

Reference will be made in detail to preferred embodiments of the invention, examples of which are illustrated in the accompanying drawings. The drawings are intended to be illustrative, not limiting. Although the invention will be described in the context of these preferred embodiments, it should be understood that it is not intended to limit the spirit and scope of the invention to these particular embodiments.

FIG. 1 shows a block diagram of voltage reference system 1;

FIG. 2 shows a block diagram of voltage reference system 50;

FIG. 3 shows a block diagram of current reference system 100;

FIG. 4 shows a diagram of bridge network 30B;

FIG. 5 shows a block diagram of voltage reference system 1A; and

FIG. 6 shows a block diagram of voltage reference system 1B.

### DETAILED DESCRIPTION OF THE INVENTION

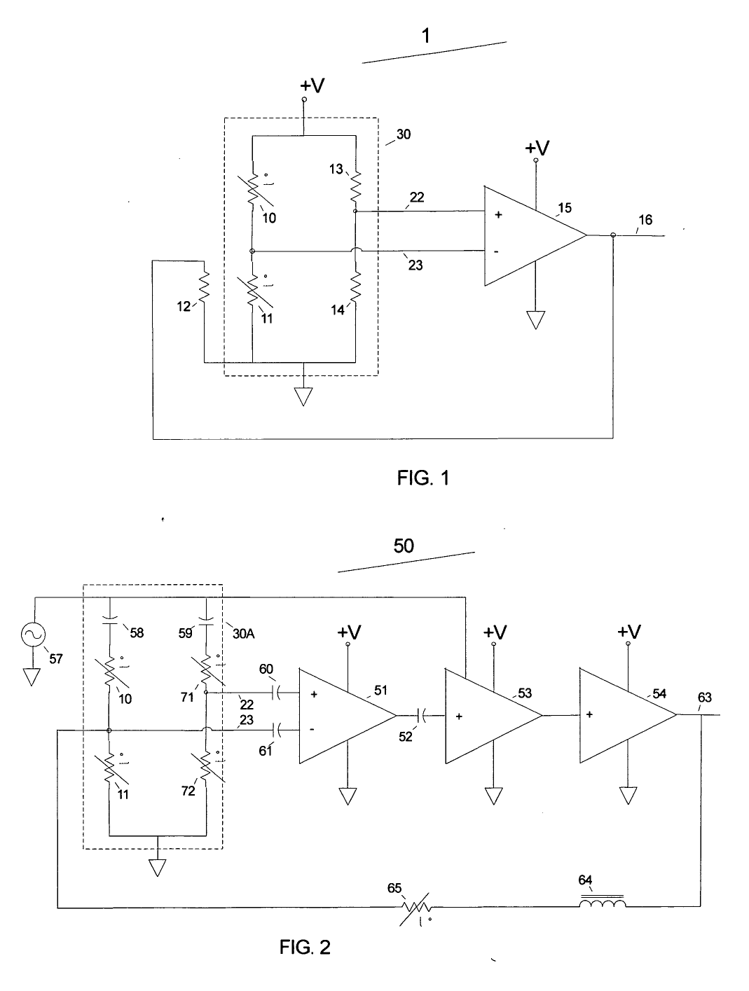

An embodiment of the invention is shown in FIG. 1. The voltage reference system 1 comprising bridge network 30 and amplifier 15 and resistor load 12.

Bridge network 30 consists of resistors 10 and 11 connected in series and resistors 13 and 14 connected in series. The other end of resistors 10 and 13 is connected to a DC voltage source, which may be the supply voltage, and the other end of resistors 11 and 14 is connected to ground. Resistors 10 and 11 are temperature sensitive resistors of substantially matching temperature coefficients and at the same ambient temperature so that the effects of ambient temperature are concealed out. Resistors 13 and 14 have substantially matching temperature coefficients to each other and are at substantially the same ambient temperature so that the effects of ambient temperature are reduced. The temperature coefficients of, resistors 13 and 14, do not need to match the temperature coefficients of, resistors 10 and 11, and they may also have very low temperature coefficients. Bridge network 30 output is the voltage level difference between line 22 and 23. The bridge network 30 resistors have high enough resistance values so as not to have a significant temperature rise caused by the DC voltage source supplying the power to it.

Amplifier 15 is a high gain differential input DC voltage amplifier receiving input voltage on line 22 and 23. An operational amplifier or a chopper style amplifier may be used. The input offset voltage of amplifier 15 is a source of error in voltage reference system 1 and various circuit techniques such as using auto zero in Amplifier 15 are well known. The voltage output of Amplifier 15 is on line 16, which is connected to resistor load 12 and is also the voltage reference system 1 output.

Resistor load 12 is connected between line 16 and ground with the power dissipated in it determined by the voltage reference system 1 output voltage on line 16. Resistor load 12 has a substantially constant resistance value and is thermally coupled to resistor 11 but is thermally isolated from the other bridge resistors. In some cases resistor load 12 can also be thermally coupled to a resistor in the other leg of bridge network 30 such as resistor 13 to increase the level of thermal coupling to bridge network 30.

As the voltage level across the resistor load 12 increases it's temperature increases causing the resistor 11 resistance to vary which causes the bridge network 30 output voltage level to vary which causes voltage reference system 1 output voltage on line 16 to vary. If for example, resistor 11 has a positive temperature coefficient, line 23 is connected to the negative input of amplifier 15 and line 22 is connected to the positive input of amplifier 15. Resistor 11 has at ambient temperature a resistance value less then resistor 10 and resistors 13 and 14 are of substantially equal value. Then as the line 16 voltage increases, the resistance of resistor 11 increases, causing the voltage level on line 23 to increase, which causes the line 16 voltage to decrease. By applying resistor load 12 temperature to resistor 11 as negative feedback the amplifier 15 output voltage level is driven to a relatively constant level that maintains the bridge network 30 output voltage level close to zero as resistor 10 becomes close to the value of resistors 10. As the gain of amplifier 15 increases the bridge network 30 output voltage level becomes closer to zero.

If instead resistor 11 has a negative temperature coefficient, line 22 is connected to the negative input of amplifier 15 and line 23 is connected to the positive input of amplifier 15. Resistor 11 would have at ambient temperature a resistance value greater then resistor 10 and resistors 13 and 14 are of substantially equal value. Then as the line 16 voltage increases, the resistance of resistor 11 decreases, causing the voltage level on line 22 to increase, which causes the line 16 voltage to decrease. By applying resistor load 12 temperature change to resistor 11 as negative feedback the amplifier output voltage level is driven to a relatively constant level that maintains the bridge network output voltage level closer to zero as the gain of amplifier 15 increases.

It is understood that resistor load 12 temperature change could be applied to any other temperature sensitive resistor besides resistor 10 in bridge network 30 without changing the concept of circuit operation.

An other embodiment of the invention is shown in FIG. 2. The voltage reference system 50 comprising bridge network 30A, AC supply 57, amplifier 51, signal detector 53, amplifier 54, inductor 64, compensation resistor 65, and AC coupling capacitors 60, 61, and 52.

Bridge network 30A consists of capacitor 58, resistors 10 and 11 connected in series and capacitor 59, resistors 71 and 72 connected in series. The other ends of capacitor 58 and capacitor 59 are connected to AC voltage supply 57, which preferably has a sine wave or square wave with substantially constant output voltage level and duty cycle. The AC voltage supply 57 output voltage level is kept low enough so as to not cause significant heating in the bridge network resistors. The other end of resistors 11 and 72 are connected to ground. Resistors 10, 11, 71 and 72 are temperature sensitive resistors of substantially matching temperature coefficients and at substantially the same ambient temperature so that the effects of ambient temperature are substantially concealed out. Resistor 11 is thermally isolated from the other resistors. Bridge network 30A output is the AC voltage level difference between line 22 and 23. The capacitance value of capacitor 58 and capacitor 59 are equal if the resistance values of resistors 11 equals that of resistors 72, and resistors 10 equals that of resistors 71 at the desired voltage level on line 63. If the resistance values are not equal then the capacitance ratio of capacitor 58 to capacitor 59 is adjusted to maintain nearly zero AC voltage level between lines 22 and 23 at the correct voltage output level of reference system 50. Resistors 72, and resistors 71 can be replaced by resistors 13 and 14 if less accuracy is permissible.

Amplifier 51 is a differential input AC voltage amplifier receiving input voltage on line 22 and 23 through AC coupling capacitors 60 and 61. An operational amplifier may be used. The input offset voltage of the amplifier is not a source of error in voltage reference system 50 since only the AC voltage level is applied to the input signal detector 53.

The AC voltage output of Amplifier 51 is connected though AC coupling capacitor 52 to the input of signal detector 53. Signal detector 53 provides synchronous rectification controlled by an other signal received from AC supply 57. Signal detector 53 responds to the AC voltage output of Amplifier when AC supply 57 output voltage level is positive to produce a low pass filtered DC voltage. The Signal detector 53 low pass filtered DC output voltage is in proportion to the positive input voltage level of signal detector 53. When AC supply 57 output voltage level is negative the Signal detector 53 provides a DC output voltage that was at the same level as when the AC supply 57 output voltage level was last positive.

Amplifier 54 is a DC voltage amplifier that is capable of supplying the necessary current and voltage levels to line 63 which is connected to the voltage reference system 50 output and also inductor 64.

Inductor 64 provides a relatively high AC impedance, compared to resistor 11, to the AC voltage signal on line 23 while allowing the DC voltage to pass through with negligible attenuation to resistor 65 which is also connected to line 23. The DC voltage on line 23 is only applied across resistor 11 since AC coupling capacitors 58, and 61 block the flow of DC current through the other bridge network 30A resistors and amplifier 51.

Compensation resistor 65 is at substantially the same ambient temperature as resistor 11 and is used to compensate for the resistor 11 change is resistance level with bridge network 30A ambient temperature. As the ambient temperature changes and causes resistor 11 resistance level to change the power dissipated in resistor 11 also change for a constant voltage level across resistor 11. Resistor 65 has a temperature coefficient that changes compensation resistor 65 resistance level with ambient temperature so as to maintain the power dissipated in resistor 11 constant for a given voltage level on line 63 even though the ambient temperature changes.

If for example, resistor 11 has a positive temperature coefficient, line 23 is connected through capacitor 61 to the negative input of amplifier 51 and line 22 is connected through capacitor 60 to the positive input of amplifier 15. Resistor 11 has at ambient temperature a resistance value less then resistor 72. As the voltage level across the resistor 11 increases it's temperature increases, but the other resistors temperatures remain relatively constant because resistor 11 is thermally isolated from them. The resistor 11 temperature increases causing the resistor 11 resistance to vary which causes the bridge network output voltage level to vary which causes voltage reference system 50 output voltage on line 63 to vary. As the line 63 voltage increases, causing the DC voltage level on line 23 to increase, causing the resistance of resistor 11 to increases which causes the Ac voltage input level to amplifier 51 to decrease. By applying the DC voltage level on line 23 to resistor 11 as negative feedback the amplifier output voltage level is driven to a relatively constant level that maintains the bridge network AC output voltage level closer to zero as the gain of amplifier 15, signal detector 53, and amplifier 54 increases.

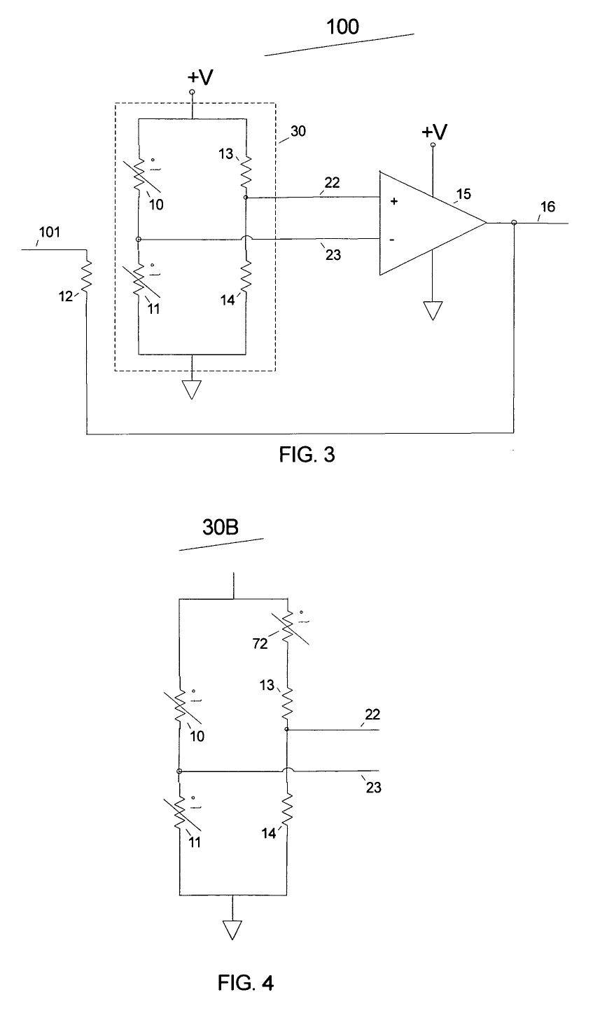

An other embodiment of the invention is shown in FIG. 3. The current reference system 100 comprising bridge network 30 and amplifier 15 and resistor load 12. This current reference system 100 functions the same way as voltage reference system 1 except that in this case the current level through resistor load 12 is maintained substantially constant.

Resistor load 12 is connected between line 16 and 101 with the power dissipated in it determined by the current level through resistor load 12 to the current reference system 100 output at line 101.

As the current level through resistor load 12 increases it's temperature increases causing the resistor 11 resistance to vary which causes the bridge network output voltage level to vary which causes voltage reference system 1 output voltage on line 16 to vary. By applying resistor load 12 temperature change to resistor 11 as negative feedback the amplifier output current level is driven to a substantially constant level that maintains the bridge network output voltage level near zero.

An other embodiment of bridge network 30 is shown in FIG. 4. Bridge network 30B is the same as Bridge network 30 except that an additional resistor is added to improve accuracy over a wide ambient temperature range.

As the ambient temperature of the temperature sensitive resistors varies any change in temperature coefficient with ambient temperature will cause the amount of resistance change to be different at different ambient temperature values for a constant input thermal or voltage signal.

Resistor 72 is inserted in series with resistors 13 between line 22 and one end of resistor 10 in Bridge network 30B. Resistor 72 is selected to have a temperature coefficient that reduces the effect of resistor 11 changes in temperature coefficient at different ambient temperatures.

As a simplified example using approximate calculations of the above, assuming resistors 13 and 14 are each 1 ohm and have a zero temperature coefficient and resistors 72 is 0 ohms. Resistor 10 is 1 ohm at 0° C. and resistor 11 is 0.91 ohm at 0° C. and both have a temperature coefficient 1%/° C. at 0° C. and 0.5%/° C. at 100° C. At 100° C., Resistor 10 is 2 ohm and resistor 11 is 1.82 ohm. A fixed heat level is applied to resistors 11 which causes a temperature increase of 10° C. At 0° C. ambient resistors 11 has changed 10% and equals 1 ohm making the voltage levels on lines 22 and 23 equal. At 100° C. ambient, resistor 11 now changes 5% and equals 1.91 ohms making the voltage levels on lines 22 and 23 unequal.

To make the voltage levels on lines 22 and 23 equal at both 0° C. and 100° C., resistor 72 is changed to 0.2 ohms with a temperature coefficient of 0.75%/° C., and resistor 13 to 0.8 ohms. At 0° C. ambient the sum of resistors 72 and resistor 13 equals 1 ohm making the voltage levels on lines 22 and 23 equal. At 100° C. ambient, resistor 72 now changes 75% and equals 0.35 ohms making the voltage levels on lines 22 and 23 again equal. By adding additional temperature sensitive resistors to Bridge network 30B, the error caused by the temperature coefficient variation of the temperature sensitive resistors can be reduced.

It is understood that the combinations of other resistors of varying temperature coefficients could also be used to obtain an equivalent Bridge network 30B network and that one resistor can replace the combination of resistors 72 and 13.

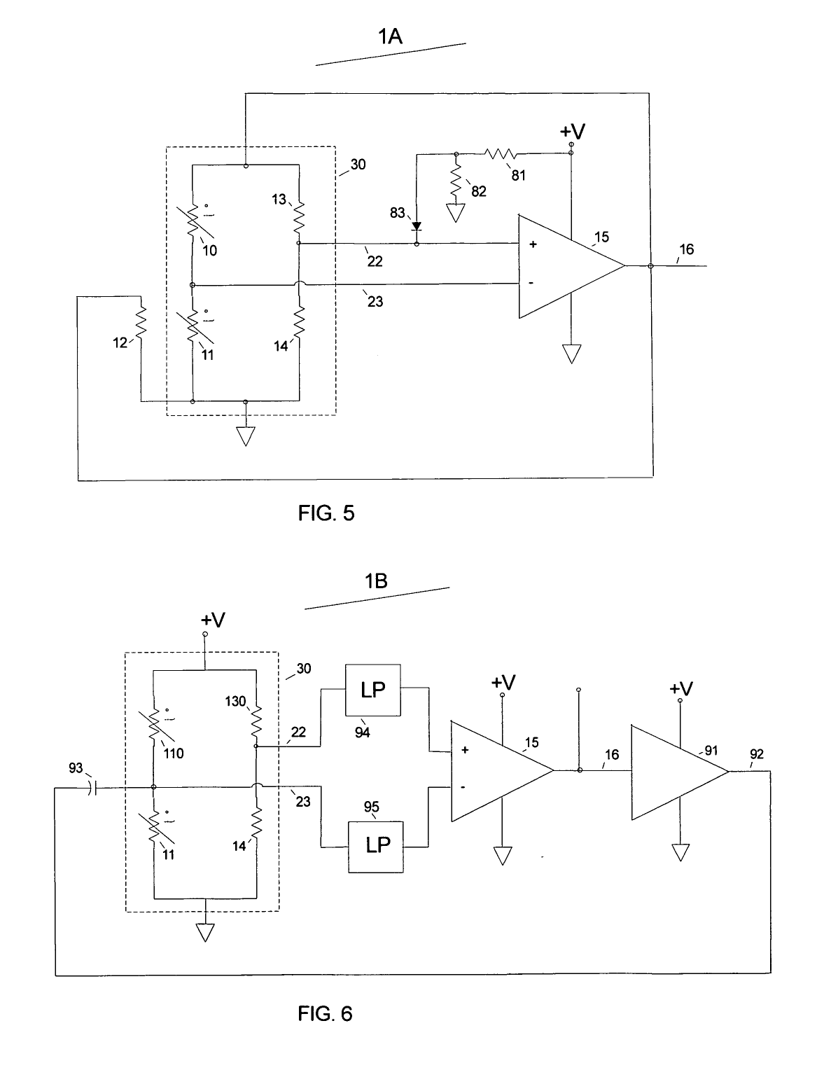

An other embodiment of the invention is shown in FIG. 5. The voltage reference system 1A comprising bridge network 30 and amplifier 15 and resistor load 12. This voltage reference system 1A functions the same way as voltage reference system 1 except that in this case bridge network 30 has one end of resistors 10 and 13 connected to voltage reference system 1A output on line 16 instead of to a DC voltage source. By using the regulated voltage level on line 16 to power bridge network 30 the voltage reference system 1A voltage regulation is improved since the power dissipated in the bridge network 30 resistors are kept substantially constant along with the common mode voltage levels on lines 23 and 22.

Resistor 81, diode 83, and resistor 82 are used to insure start up of voltage reference system 1A. Under some conditions voltage reference system 1A may operate incorrectly with the line 16 voltage level at nearly 0 volts. To insure this does not occur a low voltage level is applied to line 22 to force the line 16 voltage level to increase to the desired value.

Resistor 81 is connected to the DC voltage source and the other end is connected to diode 83 and resistor 82. Diode 83 other end is connected to line 22. The other end of resistor 82 is connected to ground. Resistor 81 and resistor 82 form a voltage divider that provides a relatively low voltage to Diode 83, compared to the normal voltage level on line 22. Diode 83 supplies voltage to line 22 when line 22 has a voltage level less than that of the voltage divider connection to the diode 83. When the voltage level on line 22 increases above that of the voltage divider connection side of diode 83, diode 83 is reverse biased and turned of.

An other embodiment of the invention is shown in FIG. 6. The voltage reference system 1B comprising bridge network 30B, amplifier 15, DC/AC converter 91, low pass filter 94, low pass filter 95, and capacitor 93. This voltage reference system 1B functions the same way as voltage reference system 1 except that in this case bridge network 30B has one end of resistors 11 and 110 connected to one end of capacitor 30. The other end of capacitor 30 is connected to the output of DC/AC converter 91. The input to DC/AC converter 91 is connected to line 16. Low pass filter 94 input is on line 22 and its output is connected to the non-inverting input of amplifier 15. Low pass filter 95 input is on line 23 and its output is connected to the inverting input of amplifier 15.

DC/AC converter 91 converts the DC signal on line 16 to a AC voltage with a level proportional to that on line 16. The AC voltage is applied to resistor 11 through capacitor 93. Resistor 110 has a significantly higher resistance level than resistor 11 so that the temperature change caused by the AC voltage is significantly less than the resistor 11 temperature change. Low pass filter 94 and low pass filter 95 both greatly reduce the AC voltage level that is applied to the input of amplifier 15. The resistance ratio of resistor 14 to resistor 130 is substantially the same ratio as resistor 11 to resistor 110 at the selected voltage level on line 16.

I claim:

1. A constant signal level system for supplying a direct current output signal in which variation in level of said output signal is reduced, comprising:
a bridge network having a differential output signal comprising at least one temperature sensitive resistor;
said differential output signal level being responsive to temperature level of said temperature sensitive resistor;
a differential-input amplifier having an amplifier output signal level responsive to said differential output signal;
temperature level of said temperature sensitive resistor being responsive to said amplifier output signal level;
whereby negative feedback is utilized to cause change of said temperature level to maintain said amplifier output signal at a substantially constant level which maintains said direct current output signal also at a substantially constant level.

2. The constant signal level system recited in claim 1 wherein further said direct current output signal is a voltage.

3. The constant signal level system recited in claim 1 wherein further said direct current output signal is a current.

4. The constant signal level system recited in claim 1 comprising at least one additional temperature sensitive resistors to reduce the effect of ambient temperature on said direct current output signal level.

5. The constant signal level system recited in claim 1 wherein further said bridge network is powered by an AC voltage source.

6. The constant signal level system recited in claim 1 wherein further said bridge network is powered by a voltage source providing a voltage level responsive to said amplifier output signal.
